(19) United States
(12) Patent Application Publication
(10) Pub. No.: US 2026/0219697 A1
(43) Pub. Date: Jul. 30, 2026

(54) CURRENT CONTROL DEVICE

(71) Applicant: Panasonic Intellectual Property Management Co., Ltd., Osaka (JP)

(72) Inventors: TAKAAKI KATO, Hyogo (JP); YO KUMODA, Osaka (JP); YUTA NAGATOMI, Osaka (JP)

(21) Appl. No.: 19/145,160

(22) PCT Filed: Nov. 6, 2023
(86) PCT No.: PCT/JP2023/039863

§ 371 Date: Jul. 1, 2025

(30) Foreign Application Priority Data
Mar. 22, 2023 (JP) 2023-045881

(51) Int. Cl. G05F 1/569; H02H 9/02

(52) U.S. Cl. CPC G05F 1/569; H02H 9/02

(57) ABSTRACT

A current control device includes an input terminal, an output terminal, a fuse, and a variable resistor unit. The input terminal is configured to be connected to a power source. The output terminal is configured to be connected to a load. The fuse is connected in an electric path electrically connecting the input terminal to the output terminal. The variable resistor unit is electrically connected in the electric path and between the fuse and the input terminal. The variable resistor unit has a resistance value configured to increase in response to an increase of a current flowing through the electric path.

### TECHNICAL FIELD

The present disclosure relates to a current control device. More particularly, the present disclosure relates to a current control device configured to reduce a current flowing from a power source to a load

### BACKGROUND ART

A protective device disclosed in PTL 1 is connected between an input power supply that supplies a direct-current (DC) electric power and a load device that receives an operation electric power from the input power supply. The protective device includes a fuse, a surge voltage absorber, a surge voltage suppression unit, a back flow prevention unit, a current reduction unit, and a filter unit. The fuse is connected in series in a connection line connecting the input power supply to the load device. The surge voltage absorber absorbs a surge voltage applied from the input power supply. The surge voltage suppression unit suppresses the surge voltage applied from the input power supply. The backflow prevention unit blocks a current flowing from the load device back to the input power supply. The current reduction unit reduces a current flowing from the input power supply to the load device. The filter unit reduces noises contained in a direct-current electric power supplied from the input power supply. The fuse, the surge voltage absorber, the surge voltage suppression unit, the back flow prevention unit, the current reduction unit, and the filter unit are connected in this order from the input power supply side to the load device side.

### CITATION LIST

### Patent Literature

PTL 1: Japanese Patent Lai-Open Publication No. 2020-167807

### SUMMARY OF INVENTION

In that case that the current reduction capability of the current reduction unit is set so as to adequately reduce an abnormal current, such as a short circuit current or an inrush current in the protection device, disclosed in PTL 1, a voltage drop at the current reduction unit increases during a normal time in which a normal current flows. This situation may cause an increase of the voltage drop to possibly affect an operation of the load device. On the other hand, in the case that the current reduction capability of the current reduction unit is set so that the voltage drop at the current reduction unit during the normal time does not affect the operation of the load device, the abnormal current is not adequately reduced by the current reduction unit. Accordingly, it is necessary to use a fuse that has a large rated breaking current, which causes a concern of cost increase. In view of the above in the field of the protection device as disclosed in PTL 1, it has been desired to properly control the current reduction capability according to changes in the current.

A current control device in an aspect of the present disclosure includes: an input terminal configured to be connected to a power source; an output terminal configured to be connected to a load; a fuse connected in an electric path electrically connecting the input terminal to the output terminal; and a variable resistor unit electrically connected in the electric path and between the fuse and the input terminal. The variable resistor unit has a resistance value configured to increase in response to an increase of a current flowing through the electric path.

The present disclosure allows the current reduction capability to be properly controlled according to a change of the current.

### BRIEF DESCRIPTION OF DRAWINGS

FIG. 1 is a schematic block diagram of a current control device according to exemplary embodiments of the present disclosure.

FIG. 2 is a circuit diagram of a current control device according to Exemplary Embodiment 1 of the present disclosure.

FIG. 3 is a graph showing a change of a resistance value of a variable resistor unit of the current control device according to the embodiments.

FIG. 4 is a circuit diagram of a current control device according to Exemplary Embodiment 2 of the present disclosure.

### DESCRIPTION OF EMBODIMENT

A current control device 1 according to exemplary embodiments of the present disclosure will be detailed below with reference to the accompanying drawings. Each exemplary embodiment and its modification described below is merely an example, and that the present disclosure is not limited by the exemplary embodiments and the modifications. Other exemplary embodiments and modifications variously changed depending on the designs and the like may be possible provided that they are not departing from the scope of the technical ideas described in the present disclosure.

### Exemplary Embodiment 1

### (1) Overview

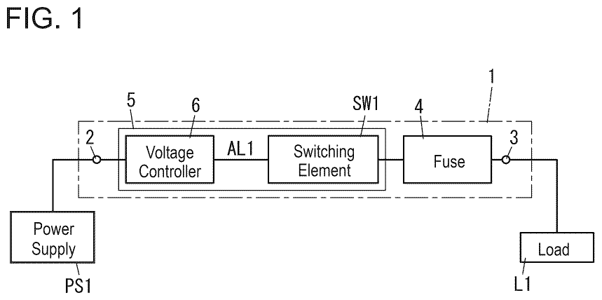

A current control device 1 according to the present exemplary embodiment will be described below with reference to FIG. 1.

The current control device 1 is a device for controlling a current flowing into a load L1 to protect the load L1 from an abnormal current, such as a short circuit current or an inrush current.

The current control device 1 is configured to be installed in, for example, a backup power supply system for use in automobiles. The current control device 1 may be installed in a power supply system for use, for example, in housing complexes, detached houses, office buildings, commercial buildings, hotels, factories or shopping stores.

The current control device 1 includes an input terminal 2, an output terminal 3, a fuse 4, and a variable resistor unit 5 as shown in FIG. 1.

The input terminal 2 is configured to be connected to a power source PS1.

The output terminal 3 is configured to be connected to a load L1.

The fuse 4 is connected in an electric path AL1 electrically connects the input terminal 2 to the output terminal 3.

The variable resistor unit 5 is electrically connected between the fuse 4 and the input terminal 2. The resistance value of the variable resistor unit 5 increases in response to an increase of a current flowing through the electric path AL1, and decreases in response to a decrease of the current.

In the above-described configuration, the resistance value of the variable resistor unit 5 increases in response to an increase of the current flowing through the electric path AL1 to allow the current reduction capability to be properly controlled in response to a change of the current flowing through the electric path AL1. In other words, in the current control device 1, the resistance value of the variable resistor unit 5 increases in response to an occurrence of an abnormal current flowing through the electric path AL1 to raise the current reduction capability. Further, it is possible to suppress the possibility that a voltage drop at the variable resistor unit 5 affects the operation of the load L1 during when the normal current flows through the electric path AL1.

In addition, the variable resistor unit 5 of the current control device 1 reduces the abnormal current, and allows the fuse 4 to be a small one having a relatively small rated breaking current. Accordingly, it is possible to suppress occurrences of problems that the cost increase and a defective matching of the fusing characteristic of the fuse 4 and the load L1 (the fuse 4 does not melt down in a case where protection of the load L1 is necessary), which would occur when a large fuse having a relatively high rated breaking current is used.

### (2) Details

The current control device 1 according to the present embodiment will be detailed below with reference to FIGS. 1-3.

### (2.1) Entire Configuration

The current control device 1 includes the input terminal 2, the output terminal 3, the fuse 4, and the variable resistor unit 5, as shown in FIG. 1.

The input terminal 2 is configured to be connected to a high potential terminal of the power source PS1, which is a direct-current (DC) power source. The power source PS1 includes, for example, a DC/DC converter or a linear regulator.

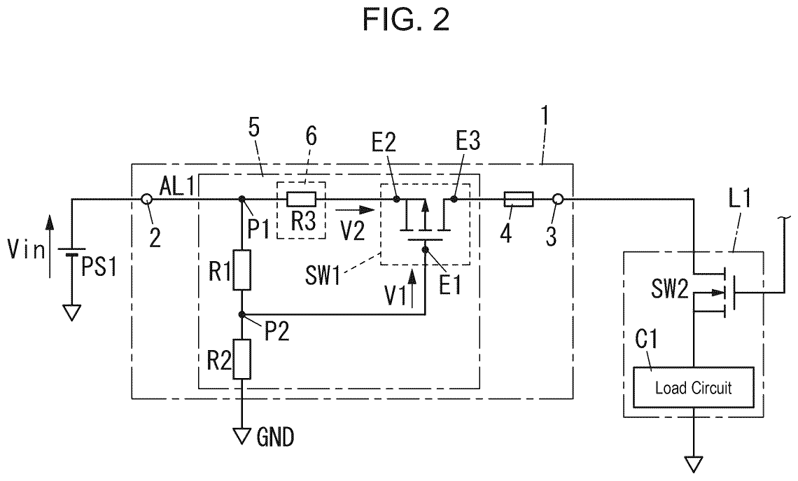

The output terminal 3 is configured to be connected to the load L1, which may be a DC load. In more detail, as shown in FIG. 2, the load L1 includes a load circuit C1 and a load switch SW2. The output terminal 3 is configured to be connected to the load switch SW2.

The load circuit C1 includes various electronic components, such as resistors and capacitors.

The load switch SW2 may be an enhancement mode N-channel metal oxide semiconductor field effect transistor (MOSFET). A gate terminal of the load switch SW2 is connected to a controller (not shown) provided in, for example, a device (e.g., a backup power supply system for automobiles) to which the current control device 1 is installed. The load switch SW2 is switched to be turned on and off by a gate voltage applied from the controller provided in the device to which the current control device 1 is installed.

When the load switch SW2 is turned on, an electric power is supplied from the power source PS1 to the load circuit C1. The load switch SW2 is not necessarily the enhancement mode N-channel MOSFET, and may be another semiconductor switching element, such as an insulated gate bipolar transistor (IGBT) or a bipolar transistor.

The fuse 4 may be a glass tube fuse. As another choice, the fuse 4 may be, for example, a ceramic fuse. As still another choice, the fuse 4 may be a patterned fuse implemented by a part of a wiring pattern of a printed circuit board thinner than the other part of the wiring pattern.

The fuse 4 is connected in the electric path AL1 electrically connecting the input terminal 2 to the output terminal 3. The fuse 4 is configured to melt when a current larger than a predetermined current value (an abnormal current) flows through the electric path AL1 so as to block the abnormal current flowing into the load L1 to protect the load L1.

The variable resistor unit 5 is electrically connected between the fuse 4 and the input terminal 2.

The variable resistor unit 5 includes a variable resistor element SW1 and a voltage controller 6. The variable resistor unit 5 further includes voltage dividing resistors R1 and R2 as shown in FIG. 2.

The variable resistor element SW1 may be, for example, an enhancement mode P-channel MOSFET as shown in FIG. 2.

The variable resistor element SW1 includes a first electrode E1 which is a gate electrode, a second electrode E2 which is a source electrode, and a third electrode E3 which is a drain electrode. The second electrode E2 is connected to the input terminal 2 through a later described resistor R3. The third electrode E3 is connected to the output terminal 3 through the fuse 4. That is, the current flowing through the electric path AL1 flows between the second electrode E2 and the third electrode E3.

The variable resistor element SW1 controls a resistance value Rds between the second electrode E2 and the third electrode E3 according to a potential difference ΔV (a gate-source voltage) between a first voltage V1 (a gate voltage) applied to the first electrode E1 and a second voltage V2 (a source voltage) applied to the second electrode E2. The potential difference ΔV is a value obtained by subtracting the value of the first voltage V1 from the value of the second voltage V2. The variable resistor element SW1 is an enhancement mode P-channel MOSFET. The resistance value Rds changes if a potential of the second electrode E2 is higher than a potential of the first electrode E1. Accordingly, the current control device 1 according to the present embodiment is controlled to operate such that the second voltage V2 becomes larger than the first voltage V1.

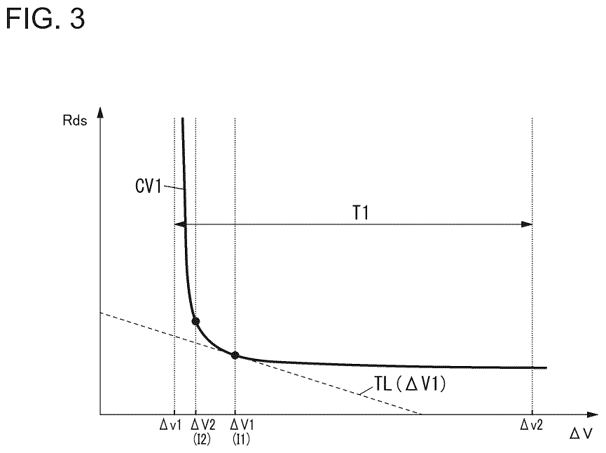

The variable resistor element SW1 is configured to operate so as to cause the resistance value Rds between the second electrode E2 and the third electrode E3 to increase as the potential difference ΔV decreases if the potential difference ΔV is within a predetermined range T1 as shown in FIG. 3. FIG. 3 is a graph with a horizontal axis representing the potential difference ΔV and a vertical axis representing the resistance value Rds.

The predetermined range T1 is a range of the potential difference ΔV in which the MOSFET operates in the so-called linear region. The linear region is a region in which the resistance value Rds of the MOSFET changes according to the potential difference ΔV. When the potential difference ΔV is larger than the upper limit of the predetermined range T1, the MOSFET saturates. When the potential difference ΔV is smaller than the lower limit of the predetermined range T1, the MOSFET is cut off. In both of the saturation region and the cut-off region, the resistance value Rds does not change according to the potential difference ΔV. In the example shown in FIG. 3, the predetermined range T1 is a range in which the potential difference ΔV takes a value between a value Av1 and a value Av2. In the predetermined range T1, the resistance value Rds diverges to infinity as the value of the potential difference ΔV becomes close to Av1, and the resistance value Rds converges to a constant value as the value of the potential difference ΔV becomes close to Av2.

The linear region is a region in which a current Id flowing from the second electrode E2 to the third electrode E3 increases as the potential difference Vds between the second electrode E2 and the third electrode E3 increases. When the MOSFET operates in the linear region, an inclination of an output characteristic (a current Id-potential difference Vds characteristic) increases as the potential difference (the gate-source voltage) ΔV increases. Since the inclination of the output characteristic (the current Id-potential difference Vds characteristic) is a reciprocal of the resistance value Rds between the second electrode E2 and the third electrode E3, the resistance value Rds decreases as the potential difference ΔV increases, and the resistance value Rds increases as the potential difference ΔV decreases in the predetermined range3 T1.

The voltage controller 6 includes a resistor R3 electrically connected between the input terminal 2 and the variable resistor element SW1 as shown in FIG. 2,

The voltage dividing resistors R1 and R² are connected in series to each other between a ground GND and a connecting point P1 on the electric path AL1 at which the input terminal 2 is connected to the resistor R3. In more detail, one end of the voltage dividing resistor R1 is connected to the connecting point P1 and the other end of the voltage dividing resistor R1 is connected to the voltage dividing resistor R2 at a connecting point P2. One end of the voltage dividing resistor R2 is connected to the voltage dividing resistor R1 at the connecting point P2, and the other end of the voltage dividing resistor R2 is connected to the ground GND. The connecting point P2 of the voltage dividing resistor R1 and the voltage dividing resistor R2 is connected to the first electrode E1 of the variable resistor element SW1.

The voltage dividing resistors R1 and R2 divide an input voltage Vin from the power source PS1 to produce the first voltage (the gate voltage) applied to the first electrode E1. The value of the first voltage V1 is expressed as vin·r1/(r1+r2), where r1 and r2 are the values of the voltage dividing resistors R1 and R2, respectively, and vin is the value of the input voltage Vin. The first voltage V1 is a voltage divided from the input voltage Vin to be smaller in value than the input voltage Vin.

### (2.2) Setting of First Voltage

The setting of the first voltage (the gate voltage) V1 will be described below with reference to FIG. 3.

As described above, the first voltage V1 is produced by dividing the input voltage Vin with the voltage dividing resistors R1 and R2. Accordingly, the value of the first voltage V1 may be set by selecting the resistance values of the voltage dividing resistors R1 and R2. The first voltage V1 is constant as far as the input voltage Vin is constant.

In accordance with the present embodiment, the value of the first voltage V1 is set such that the potential difference ΔV is within the predetermined range T1 if the current value of the current flowing through the electric path AL1 is a predetermined current value i1 which is equal to or smaller than the rated current of the fuse 4. The predetermined current value i1 equal to or smaller than the rated current of the fuse 4 may be, for example, a current value of a normal current I1 flowing through the electric path AL1 when the load L1 operates normally. In other words, a potential difference ΔV(I1), which is the potential difference ΔV while the normal current I1 flows through the electric path AL1, is within the predetermined range T1 as shown in FIG. 3.

The voltage drop at the resistor R3 while the normal current I1 flows into the load L1 is expressed as i1·r3, where r3 is the resistance value of the resistor R3. The value of the potential difference ΔV1 (I1) while the normal current I1 flows into the load L1 is expressed as vin−i1·r3−v1, where v1 is the value of the first voltage V1, and vin is the value of the input voltage Vin. In other words, the first voltage V1 may be set such that the value of vin-i1·r3−v1 takes a value between the value Av1 to the value Av2. In addition to setting the value of the first voltage V1, the value of the resistor R3 may be set such that the value of vin−i1·r3−v1 takes a value between the value Av1 and the value Av2. The value between the value Av1 and the value Av2 may be, for example, a value that is larger than Av1 and smaller than Av2. As another condition, the value between the value Av1 and the value Av2 may be a value that is larger than Av1 and equal to or smaller than Av2.

In more detail, the value v1 of the first voltage V1 is set such that a ratio of an absolute value of a change of the resistance value Rds to an absolute value of a change of the potential difference ΔV becomes a predetermined value if the current value of the current flowing through the electric path AL1 is the predetermined current value i1 that is equal to or smaller than the rated current of the fuse 4. Here, the ratio of the absolute value of the change of the resistance value Rds to the absolute value of the change of the potential difference ΔV corresponds to an absolute value of an inclination of a tangent line TL to a curve CV1 shown in FIG. 3. In other words, the value v1 of the first voltage V1 is set such that the absolute value of the inclination of the tangent line TL(ΔV1) becomes a predetermined value, where the tangent line TL(ΔV1) is a tangent line TL to the curve CV1 when the potential difference ΔV is the potential difference ΔV1(I1) of the normal current I1 flows through the electric path AL1. The predetermined value may preferably be in a range from 0.1 to 0.3 provided that the unit of the resistance value Rds is “mΩ” (milliohm) and the unit of the potential difference ΔV is “V” (volt).

In the predetermined range T1, as shown in FIG. 3, the absolute value of the inclination of the tangent line TL decreases as the potential difference ΔV increases, and the absolute value of the inclination increases as the potential difference ΔV decreases. Accordingly, when the potential difference ΔV becomes smaller than the potential difference ΔV1(I1) in the predetermined range T1, the absolute value of the inclination of the tangent line TL becomes larger than the predetermined value, so that the resistance value Rds increases steeply. When the potential difference ΔV becomes larger than the potential difference ΔV1(I1) in the predetermined range T1, the absolute value of the inclination of the tangent line TL becomes smaller than the predetermined value, so that the resistance value Rds decreases.

### (2.3) Operation Example

An operation example of the current control device 1 will be described below with reference to FIGS. 2 and 3. In the example described below, the load switch SW2 is initially turned off.

First, when the load switch SW2 is controlled to be turn on by a controller (not shown) provided in a device (for example, a backup power supply system for an automobile) to which the current control device is installed, an electric power is supplied from the power source PS1 to the load circuit C1.

At this moment, in a case where the load circuit C1 includes a capacitor having a capacitive component, an inrush current I2 flows from the power source PS1 to the load circuit C1.

The value of a potential difference ΔV2(I2) which is the potential difference ΔV when the inrush current I2 flows through the electric path AL1 becomes vin−i2·r3−v1, where i2 is the value of the inrush current I2. Here, the value i2 of the inrush current I2 is larger than the predetermined current value i1 (the current value of the normal current I1). That is, the voltage drop i2·r3 at the resistor R3 becomes larger than the voltage drop i1·r3 at the resistor R3 when the normal current I1 flows into the load L1. Accordingly, the value vin-i2·r3−v1 of the potential difference ΔV2(I2) when the inrush current I2 flows through the electric path AL1 becomes smaller than the value vin−i1·r3−v1 of the potential difference ΔV1(I1) when the normal current I1 flows into the load L1. In other words, the current controller 6 having the resistor R3 decreases the potential difference ΔV in response to an increase of the current flowing through the electric path AL1.

When the potential difference ΔV decreases from the potential difference ΔV1(I1) to the potential difference ΔV2(I2), the resistance value Rds between the second electrode E2 and the third electrode E3 increases steeply as shown in FIG. 3, thereby reducing the inrush current I2.

After the capacitor included in the load circuit C1 is fully charged, the above-described normal current I1 starts to flow through the electric path AL1. At this moment, the potential difference ΔV changes from the potential difference ΔV2(I2) to the potential difference ΔV1(I1), thereby decreasing the resistance value Rds steeply. That is, the voltage drop at the variable resistor element SW1 decreases. This configuration prevents the voltage drop at the variable resistor unit 5 from affecting the load L1 while the normal current I1 flows through the electric path AL1.

In a case where a short circuit current larger than the normal current I1 flows through the electric path AL1, the voltage controller 6 reduces the potential difference ΔV in response to an increase of the current flowing through the electric path AL to increase the resistance value Rds steeply, similarly to the case that the inrush current I2 flows through the electric path AL2, thereby reducing the short circuit current.

### Exemplary Embodiment 2

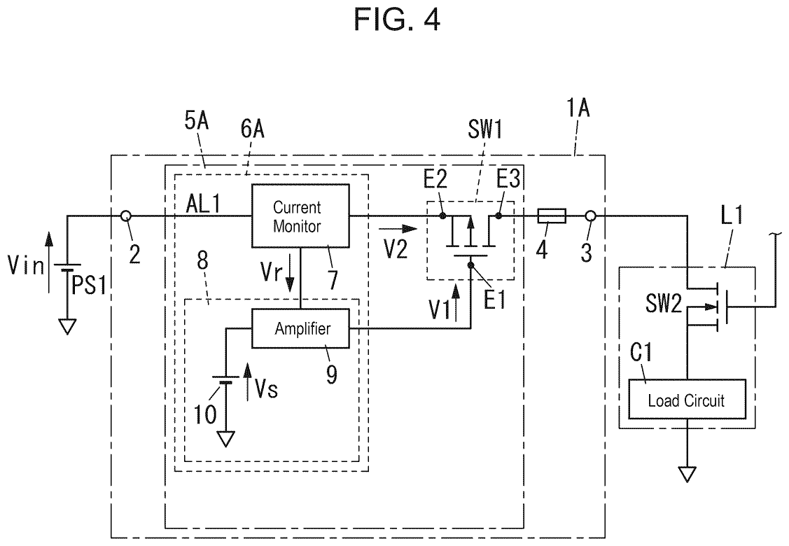

A current control device 1A according to Exemplary Embodiment 2 will be described below with reference to FIG. 4. In the following description, structural components identical to those of Embodiment 1 will be denoted by the reference numerals, and duplicate description thereof them will be omitted.

The current control device 1A according to the present embodiment includes the input terminal 2, the output terminal 3, the fuse 4, and a variable resistor unit 5A.

The variable resistor unit 5A is electrically connected between the fuse 4 and the input terminal 2. The variable resistor unit 5A includes a variable resistor element SW1 and a voltage controller 6A.

The voltage controller 6A includes a current monitor 7 configured to detect a current flowing through the electric path AL1, and a first voltage controller 8 configured to control the first voltage V1 based on a detection result by the current monitor 7. In the current control device 1 according to Embodiment 1 shown in FIG. 2, the first voltage V1 is constant. However, in the current control device 1A according to Embodiment 2 shown in FIG. 4, the first voltage V1 changes depending on the electric path AL1.

The current monitor 7 is electrically connected between the input terminal 2 and the second electrode E2 of the variable resistor element SW1. The current monitor 7 includes, e.g., a shunt resistor electrically connected between the input terminal 2 and the variable resistor element SW1. In this case, the current monitor 7 outputs a voltage Vr across the both ends of the shunt resistor, which is proportional to the current flowing through the electric path AL1, to an amplifier 9 provided in a later-described first voltage controller 8.

The first voltage controller 8 includes a reference voltage generator 10 and the amplifier 9.

The reference voltage generator 10 is configured to generate a reference voltage Vs. The reference voltage generator 10 is configured to output the generated reference voltage Vs to the amplifier 9.

The amplifier 9 is configured to amplify a difference between the reference voltage Vs and the voltage Vr which is proportional to the current detection result by the current monitor 7. The amplifier 9 may be, for example, a differential amplifier. The amplifier 9 amplifies a difference (potential difference) between the voltage Vr and the reference voltage Vs by a predetermined gain, and outputs the amplified voltage as the first voltage V1 to the first electrode E1.

The reference voltage Vs is set, for example, such that the potential difference ΔV between the first voltage V1 and the second voltage V2 becomes ΔV1(I1) if the normal current I1 (refer to Embodiment 1) flows through the electric path AL1. In other words, the amplifier 9 outputs, to the first electrode E1, the first voltage V1 causing the potential difference ΔV to become ΔV1(I1) if the normal current I1 flows through the electric path AL1.

When an abnormal current larger than the normal current I1 flows through the electric path AL1, the difference between the reference voltage Vs and the voltage Vr proportional to the current detection result by the current monitor 7 increases. That is, when the abnormal current larger than the normal current I1 flows through the electric path AL1, the value of the first voltage V1 output from the amplifier 9 increases. This configuration reduces the potential difference ΔV. When the potential difference DV is reduced from the potential difference DV1(I1), the resistance value Rds between the second electrode E2 and the third electrode E3 increases steeply as shown in FIG. 3, thereby reducing the abnormal current.

### Modifications

Each of the above-described exemplary embodiments is merely one of various exemplary embodiments of the present disclosure. Each of the above-described exemplary embodiments may be modified depending on the designs and the like as far as the object of the present disclosure can be achieved. Hereinafter, modifications of the above-described exemplary embodiments will be listed. The modifications described below may be appropriately combined for applications.

The current control device 1 in accordance with the above-described embodiments has a configuration which does not include the power source PS1. However, the present disclosure may not be limited to such configuration, and the current control device 1 may include the power source PS1.

The variable resistor element SW1 is not necessarily the enhancement mode P-channel MOSFET, but may be another semiconductor switching element, such as an insulated gate bipolar transistor (IGBT) or a bipolar transistor.

The current monitor 7 in accordance with Embodiment 2 is not necessarily the shunt resistor, but may be, for example, an open-loop or closed-loop magnetic sensor.

### SUMMARY

As described hereinabove, a current control device (1) in accordance with a first aspect includes: an input terminal (2) configured to be connected to a power source (PS1); an output terminal (3) configured to be connected to a load (L1); a fuse (4) connected in an electric path (AL1) electrically connecting the input terminal (2) to the output terminal (3), and a variable resistor unit (5) electrically connected between the fuse (4) and the input terminal (2) in the electric path (AL1). The variable resistor unit (5) has a resistance value (Rds) configured to increase in response to an increase of a current flowing through the electric path (AL1).

According to this aspect, the resistance value (Rds) of the variable resistor unit (5) increases in response to an increase of the current flowing through the electric path (AL1), so that the current reduction capability is be properly controlled according to changes of the current flowing through the electric path (AL1).

In a current control device (1) in accordance with a second aspect, according to the first aspect, the variable resistor unit (5) includes a variable resistor element (SW1) and a voltage controller (6). The variable resistor element (SW1) includes a first electrode (E1), a second electrode (E2), and a third electrode (E3). The variable resistor element (SW1) is configured to control the resistance value (Rds) between the second electrode (2) and the third electrode (E3) according to a potential difference (ΔV) between a first voltage (V1) applied to the first electrode (E1) and a second voltage (V2) applied to the second electrode (E2). The variable resistor element (SW1) is configured to increase the resistance value (Rds) between the second electrode (E2) and the third electrode (E3) in response to a decrease of the potential difference (ΔV) if the potential difference (ΔV) is within a predetermined range (T1). The current flowing through the electric path (AL1) flows between the second electrode (E2) and the third electrode (E3). The voltage controller (6) is configured to decrease the potential difference (ΔV) in response to an increase of the current flowing through the electric path (AL1).

According to this aspect, the resistance value (Rds) between the second electrode (E2) and the third electrode (E3) increases in response to an increase of the current flowing through the electric path (AL1), so that the current reduction capability can be properly controlled according to a change of the current flowing through the electric path (AL1).

In a current control device (1) in accordance with a third aspect, according to the second aspect, a value of the first voltage (V1) is set such that the potential difference (ΔV) becomes within a predetermined range (T1) if the current value of the current flowing through the electric path (AL1) is a predetermined current value (i1) that is equal to or smaller than a rated current of the fuse (4).

According to this aspect, the potential difference (ΔV) decreases to increase the resistance value (Rds) when an abnormal current larger than the rated current of the fuse (4) flows through the electric path (AL1).

In a current control device (1) in accordance with a fourth aspect, according to the third aspect, a value of the first voltage (V1) is set such that a ratio of an absolute value of a change of the resistance value (Rds) to an absolute value of a change of the potential difference (ΔV) becomes a predetermined value if the current value of the current flowing through the electric path (AL1) is the predetermined current value (i1) that is equal to or smaller than the rated current of the fuse (4).

According to this aspect, the potential difference (ΔV) decreases to increase the resistance value (Rds) when an abnormal current larger than the rated current of the fuse (4) flows through the electric path (AL1).

In a current control device (1) in accordance with a fifth aspect according to any of the second to fourth aspects, the voltage controller (6) includes a resistor (R3) electrically connected between the input terminal (2) and the variable resistor element (SW1).

According to this aspect, a voltage drop at the resistor (R3) increases when an abnormal current flows through the electric path (AL1), thereby decreasing the potential difference (ΔV).

In a current control device (1) in accordance with a sixth aspect according to the second aspect, the voltage controller (6) includes a current monitor (7) configured to detect the current flowing through the electric path (AL1), and a first voltage controller (8) configured to control the first voltage (V1) based on a detection result by the current monitor (7).

According to this aspect, the resistance value (Rds) between the second electrode (E2) and the third electrode (E3) increases in response an increase of the current flowing through the electric path (AL1), so that the current reduction capability can be properly controlled according to changes of the current flowing through the electric path (AL1).

In a current control device (1) in accordance with a seventh aspect according to the sixth aspect, the first voltage controller (8) includes an amplifier (9) configured to amplify a difference between a reference voltage (Vs) and a voltage (Vr) proportional to the detection result of the current flowing through the electric path (AL1) by the current monitor (7).

According to this aspect, the resistance value (Rds) between the second electrode (E2) and the third electrode (E3) increases in response an increase of the current flowing through the electric path (AL1), so that the current reduction capability is properly controlled according to a change of the current flowing through the electric path (AL1).

The configurations in the second through seventh aspects are not essential for the current control device (1), and may appropriately be omitted.

### REFERENCE MARKS IN THE DRAWINGS

1 current control device
2 input terminal
3 output terminal
4 fuse
5 variable resistor unit
6 voltage controller
7 current monitor
8 first voltage controller
9 amplifier
AL1 electric path
E1 first electrode
E2 second electrode
E3 third electrode
i1 predetermined current value
L1 load
PS1 power source
R3 resistor
Rds resistance value
SW1 variable resistor element
T1 predetermined range
V1 first voltage
V2 second voltage
Vr voltage
Vs reference voltage
ΔV potential difference

1. A current control device comprising:
an input terminal configured to be connected to a power source;
an output terminal configured to be connected to a load;
a fuse disposed on an electric path electrically connecting the input terminal to the output terminal; and
a variable resistor unit electrically connected in the electric path and between the fuse and the input terminal, the variable resistor unit having a resistance value configured to increase in response to an increase of a current flowing through the electric path.

2. The current control device according to claim 1, wherein
the variable resistor unit includes a variable resistor element and a voltage controller,
the variable resistor element includes a first electrode, a second electrode, and a third electrode,
the variable resistor element is configured to:
controlling a resistance value between the second electrode and the third electrode according to a potential difference between a first voltage applied to the first electrode and a second voltage applied to the second electrode; and
increase the resistance value between the second electrode and the third electrode in response to a decrease of the potential difference if the potential difference is within a predetermined range,
the current is configured to flow between the second electrode and the third electrode, and
the voltage controller is configured to decrease the potential difference in response to an increase of the current.

3. The current control device according to claim 2, wherein a value of the first voltage is set such that the potential difference becomes within the predetermined range if a current value of the current is a predetermined current value equal to or smaller than a rated current of the fuse.

4. The current control device according to claim 3, wherein a value of the first voltage is set such that a ratio of an absolute value of a change of the resistance value to an absolute value of a change of the potential difference becomes a predetermined value if the current value of the current is the predetermined current value.

5. The current control device according to claim 2, wherein the voltage controller includes a resistor electrically connected between the input terminal and the variable resistor element.

6. The current control device according to claim 2, wherein the voltage controller includes:
a current monitor configured to detect the current; and
a first voltage controller configured to control the first voltage based on a detection result by the current monitor.

7. The current control device according to claim 6, wherein the first voltage controller includes an amplifier configured to amplify a difference between a reference voltage and a voltage proportional to the detection result of the current by the current monitor.
